(19) United States
(12) Patent Application Publication
(10) Pub. No.: US 2001/0045835 A1
(43) Pub. Date: Nov. 29, 2001

(54) Method and apparatus for detecting timing belt damage by inductive coupling

(76) Inventor: Adel Abdel Aziz Ahmed, Princeton, NJ (US)

Correspondence Address: Adel A. Ahmed, 160 Ridgeview Circle, Princeton, NJ, 08540, US

(21) Appl. No.: 09/791,185

(22) Filed: Feb. 23, 2001

Related U.S. Application Data
(60) Provisional application No. 60/184,996, filed on Feb. 25, 2000.

(51) Int. Cl. G01R 31/08

(52) U.S. Cl. 324/526

(57) ABSTRACT

A sensing coil is mutually inductively coupled with the coil formed by a wire loop embedded in a belt, as in a timing belt as for a camshaft drive in an internal combustion engine. When the embedded wire loop breaks, a circuit senses the change in impedance in the sensing coil and operates an alarm. The method is non-contacting with the belt and requires no sliding contacts.

Reference is hereby made to copending Provisional Patent application Serial No. 60/184,996, entitled METHOD AND APPARATUS FOR DETECTING TIMING BELT DAMAGE BY NON-CONTACTING INDUCTIVE COUPLING, filed on Feb. 25, 2000 in the name of Adel A. Ahmed, the present inventor herein, and whereof the disclosure is hereby incorporated herein by reference.

The present invention relates generally to belt drives and more particularly to a method and apparatus for protection from damage following failure of, for example, a toothed belt drive as utilized for example in timing belt applications. Timing belt failure may result in expensive damage and/or dangerous consequences, so that the detection of incipient belt failure in this application is very useful and important.

Toothed belt drives are commonly utilized for mechanical power transmission, particularly where a correct angular relationship or “timing” between a driving shaft and a driven shaft needs to be accurately maintained.

Vehicles utilizing internal combustion engines typically have a camshaft with spaced cams mounted on the camshaft for opening and closing engine valves in accordance with the requirements of the engine operating cycle. Some engines use a single camshaft whereas others utilize a plurality of camshafts, for example, two camshafts. The camshafts are typically driven by the engine crankshaft which also transmits the engine power through the vehicle transmission to the wheels.

A typical application for a toothed belt drive is, for example, in a four-stroke cycle automotive engine wherein a camshaft used for operating valves runs at one-half the angular velocity or, otherwise expressed, at one-half the revolutions per minute (rpm) of the crankshaft that drives it by way of the toothed belt and wherein the angular position relationship or timing of the camshaft and crankshaft needs to be maintained accurately.

Traditionally in the past, “link” or bicycle chain type timing chains, sometimes utilizing double side by side chains, have been used in car engines to couple the crankshaft to the camshaft, using a driven camshaft sprocket having twice as many teeth as a driving crankshaft sprocket. In some engines, a timing gear train has been used to drive the camshaft from the crankshaft.

Chains and gears are both capable of driving a camshaft while maintaining the required timing relationship between the camshaft and the crankshaft. However, the high cost of chain and gear drives and, to some extent, their operating noise level have more recently led to the widespread use of toothed belts for coupling the crankshaft and the camshaft in automotive engines, particularly in smaller engines. A toothed belt drive is quiet and well suited to driving the camshaft while maintaining the required timing relationship to the crankshaft. The same timing belt drive may also be used to drive, for example, a fuel injection pump, an ignition distributor, or some other accessory.

Examples of toothed belt and timing chain drives may be found in, for example, U.S. Pat. No. 5,463,898 entitled METHOD OF DETECTING TIMING APPARATUS MALFUNCTION IN AN ENGINE issued Nov. 7, 1995 in the name of Blander et al.; and U.S. Pat. No. 5,689,067 entitled DIAGNOSTIC METHOD AND APPARATUS FOR MONITORING THE WEAR OF AT LEAST AN ENGINE TIMING CHAIN issued Nov. 18, 1997 in the name of Klein et al., whereof the disclosure is herein incorporated by reference to the extent it is not incompatible with the present invention.

While a toothed timing belt drive offers advantages, the likelihood of belt failure is present. If a timing belt breaks in such an engine, the camshaft will very soon stop rotating, while the crankshaft will typically continue to turn for a time, either due to its rotational momentum and/or because it is coupled to the driving wheels which continue to turn because of the vehicle's momentum.

In some cases, repairing the engine following such a timing belt failure may merely require realigning the camshaft and the crankshaft into proper relationship and replacing the belt. Naturally, the vehicle will be inoperable until the belt is replaced, generally in a repair shop, and the operator may be stranded. Furthermore, since a broken timing belt can cause instant and total loss of power at an unexpected moment, a potentially hazardous traffic situation can result.

Furthermore, , in a number of engines utilizing a high compression ratio, clearance space at the top of the cylinders may be very restricted such that the pistons can only move freely to the top of their stroke with valves in the closed position.

In such an engine, if the crankshaft is rotating and the camshaft stops so that a valve is held open by its cam, interference between a piston and a stopped valve can occur so that a piston can collide with the stopped valve. This generally leads to extensive damage, and possibly ruining the engine so that the cost of repair is no longer economically justifiable. The likelihood that the problem of valve/piston interference will occur in at least one cylinder of such an engine is generally very high upon loss of a timing belt.

When such interference occurs after timing belt breakage, damage may range from a bent valve, and/or a hole in a piston, damage to a cylinder head and/or a camshaft, a gouged cylinder head, to a completely ruined engine.

As was stated above, the problem of serious damage following timing belt failure is very likely to occur in high compression ratio engines. These include many high-performance engines and compression-ignition or “diesel” engines wherein the very high compression ratio needed for ignition generally leaves insufficient room for a piston to avoid hitting a valve held open by an inoperative camshaft. Despite the problems consequent on timing belt failure, car manufacturers continue to build such “interference engines” which exhibit the problem, apparently because a “free-running engine” with enough clearance results in lower performance. The problem represents a weak point in engine reliability and, given the usually catastrophic damage resulting from timing belt failure, is likely to result in lowering of customer confidence in the product.

The problem of serious damage caused by timing belt failure in automotive engines has been addressed to some extent by maintenance schedules for periodically replacing toothed timing belts in such engines at an interval based on the average life expectancy of such belts. For example, an extensive list of “interference engines”, that is, engines where serious damage is likely following timing belt failure, was made available by The Gates Rubber Company on the Internet at the address http://www.gates.com/interfer.html. Manufacturer's service manuals generally suggest periodic replacement of the belt as precautionary maintenance every 60,000 to 80,000 miles of driving or so.

However, even periodic scheduled belt replacement can, at best, only reduce the average probability of belt failure: an individual belt may exhibit a shorter operating life than the average and, even with a new belt installed, initial failure remains a possibility, resulting in expensive damage to an engine. Generally, the timing belt in a typical automotive engine is not readily visible to the operator and regular inspection to ascertain the condition of a timing belt is inconvenient, even if it were a reliable way of predicting failure.

Typically, timing belt replacement as a maintenance service requires to be performed by qualified personnel in a repair shop and so is typically not an inexpensive job. In practice, it may not always be performed at the recommended intervals.

Reference is made to applicant's application Ser. No. 09/067,390, entitled METHOD AND APPARATUS FOR TIMING BELT DRIVE, filed Apr. 28, 1998, issued Jan. 30, 2001 as U.S. Pat. No. 6,181,239, and which, in one aspect, discloses a timing belt system for an engine which includes a first timing belt coupling the camshaft to the crankshaft; a second timing belt coupling the camshaft to the crankshaft; a belt sensor coupled to at least one of the first and second timing belts; and an alarm coupled to the belt sensor. In accordance with an aspect of this patent, a method for driving a camshaft from a crankshaft of an automotive engine comprises: operating first and second toothed belts in parallel so that the engine exhibits a first mode of operation wherein both the first and second timing belts are operating, and a second mode of operation wherein one of the first and second timing belts is broken and only one of the first and second belts is operating; detecting when engine operation changes from the first mode of operation to the second mode of operation; and thereupon operating an alarm.

The question of timing belt failure and maintenance is extensively referenced in the references cited in the aforementioned U.S. Pat. No. 6,181,239 to which attention is hereby directed.

The problem of belt failure has been addressed in, for example, U.S. Pat. No. 4,488,363 entitled COMBINATION IDLER AND BELT FAILURE SWITCH FOR A DRYER issued Dec. 18, 1984 in the name of Jackson et al., whereof the disclosure is herein incorporated by reference to the extent it is not incompatible with the present invention. In this patent, an arrangement is disclosed for terminating the operation of a dryer upon breakage of the drive belt. It is herein recognized that such an approach will not be useful in avoiding damage due to timing belt failure in an automotive engine, since failure of the timing belt may cause damage to follow immediately upon belt failure and the engine typically cannot practicably be stopped before the damage has taken place.

U.S. Pat. No. 4,626,230 entitled DEVICE FOR SENSING DAMGE TO A COGGED BELT issued Dec. 2, 1986 in the name of Yasuhara discloses a device that senses deformation of the belt resulting from damage to at least one of the teeth on the belt. The device senses an opening betwen the belt and the pulley which results from breakage of at least one of the teeth on the belt. When such displacement or an opening is detected, an indicator lamp is lit to report that the belt should be replaced. However, if the belt itself breaks as a result of a damaged tooth, engine damage may still occur.

U.S. Pat. No. 5,994,712 entitled BELT FLAW DETECTOR issued Nov. 30, 1999 and filed Jul. 29, 1997 in the name of Mack discloses a belt flaw detector that has a light source, a sensor, and processing and signaling means to indicate and warn of the flaw in the belt.

An English-language version of Patent Abstracts of Japan, Publication Number 0906069 A entitled MONITOR FOR CUTTING OF TIMING BELT OF ENGINE published Apr. 3, 1997 in the name of Takahiro discloses an “extremely small conductor” buried under the surface of a timing belt which is disposed between the camshaft and crankshaft of an engine, and which is put into contact with two contacts for supplying a current while the shafts are rotated. A contact setting device is supplied with power from the battery of an automobile and a very small current is passed through one contact, the conductor and the other contact. When the belt is cut, the conductor is cut and the current is cut and under this condition, a signal operates a warning device to warn a driver that the belt is cut, thereby preventing “a secondary disaster” or accident.

As understood from an English-language translation, Japanese patent document No. 9-60694, entitled in a translation “A DEVICE FOR MONITORING ANY CUTOFF OF A TIMING BELT IN AN ENGINE” discloses a conductive wire embedded along with the outer surface of the timing belt. A minute current flows from one contact of a roller form and which rotates in contact with the outer surface of the timing belt, to the conductive wire and further flows to another contact to a controller. In accordance with the translation, if the conductive wire is cut, the controller fails to detect the specified current and an alarm is operated. Other arrangements are also described for monitoring rotation time and ductility of the belt.

Korean patent document No. 169630 with the translated title “AN EARLY SENSING DEVICE FOR SENSING ANY DAMAGE OF A TIMING BELT EARLY IN AN INTERNAL COMBUSTION ENGINE” discloses, in an English language translation, a coil made of a conductor, which is embedded in the inside of the timing belt along with the gear teeth configuration and a steel wire connected with the coil, which is installed in the outer face of the timing belt so that the steel wire may be exposed to the outside of the timing belt. The disclosed arrangement also consists of a sensor supported by a separate supporter, which is installed in contact with the steel wire, an electronic controller through which the sensor is connected with and alarm, and alarm to give an alarm signal depending upon the signal sensed by the sensor.

According to the translation of Korean patent document No. 169630, in case a gear tooth of the timing belt is lost, the coil embedded in the inside of the timing belt along with the gear tooth configuration gets to be cut off. If a tooth formed in the timing belt is cut off, the coil embedded in the gear tooth “also gets to be short-circuited (sic)” (so stated in the translation) and therefore the electrical resistance of the coil and the steel wire “gets to be increased infinitely” and the sensor in contact with the steel wire senses the increased electrical resistance and generates a corresponding signal.

Korean patent document No. 169630 also states, in translation, that the steel wire is exposed to the outside of the timing belt so that it may be in direct contact with the sensor or the outer face of the timing belt can be coated with any coating agent having conductivity so that such coating agent may be electrically connected with the coil embedded in the inside of the timing belt and further the sensor may be in contact with the conductive coating agent.

Korean patent document No. 169630 states that the sensor can be of various types. The document discloses a sensor of the contact type and this is stated to be the most preferable sensor for sensing the electrical resistance of the coil and the steel wire. It is further stated in translation in Korean patent document No. 169630 that the sensor can be of the non-contact type so that “such cutoff may be directly and immediately sensed by the sensor. However, it is noted that Korean patent document No. 169630 states that such non-contact type is not preferable because it requires a complicated installation and operation as well as a high cost.”

The disclosure of the foregoing documents is hereby incorporated by reference to the extent that it is not incompatible with the present invention.

Both Japanese patent document No. 9-60694 and Korean patent document No. 169630 monitor electrically the condition of a wire embedded in a timing belt through mechanical touching of the wire by electrical contacts. Upon undue stretching or deformation of the timing belt, the condition of the wire is altered. The embedded wire can be arranged to break upon the fracture of a belt tooth or undue extension of the belt, either of which conditions can be a precursor of an imminent break in the belt. An early warning can therefore be given of an expected break in a relatively short time, if such systems were to operate reliably.

However, both Japanese patent document No. 9-60694 and Korean patent document No. 169630 use electrical contacts touching rapidly moving wires, so that the contact either slides or rolls on the wire for passing a monitoring current through the imbedded wire for signaling a change in its electrical resistance. It is herein recognized that such sliding or rolling contacts running against a small, fast-moving conductor are notoriously difficult to maintain reliably. Unreliable sliding contacts, particularly for small currents, are known from many everyday examples. A common example is the operation of typical low-voltage electric toy trains, where specks of dirt, rail oxidation, and contact pressure variations tend to interfere with the operation. Sliding contacts against a fine wire embedded in a moving belt are likely to be highly problematic in practice, particularly in the environment under the engine hood of an automobile vehicle. Fast sliding at high RPM, prolonged non-use, movement, wear, vibration, irregularity in the belt, and dirt and oxidation deposits are likely to render the contact erratic, thereby making the system unreliable and subject to wear. Contact wear may necessitate frequent and regular contact replacement at an expense comparable to opening the timing belt compartment for belt examination or replacement and is therefore likely to be neglected. Furthermore, such unreliable operation is particularly undesirable in a warning system for indicating timing belt damage. Typically, an erratic or unreliable warning light or sound will annoy the user and will eventually tend to be ignored, thereby defeating the purpose.

In accordance with an aspect of the invention, a sensing coil is mutually inductively coupled with the coil formed by a wire loop embedded in a belt, as in a timing belt as for a camshaft drive in an internal combustion engine. When the embedded wire loop breaks, a circuit senses the change in impedance in the sensing coil and operates an alarm. The method is non-contacting with the belt and requires no sliding contacts.

In accordance with another aspect of the invention, apparatus for detecting a break in a wire loop embedded in a timing belt, comprises an inductance loop coupled by mutual inductance to the wire loop; impedance-measuring apparatus coupled to the inductance loop; and threshold detecting apparatus coupled to the impedance-measuring apparatus. It is noted that less than a complete break can also be detected, provided the loop impedance is affected.

In accordance with another aspect of the invention, apparatus for detecting a change in a wire loop associated with a drive belt, comprises apparatus inductively coupled to the wire loop for sensing a change of impedance of the wire loop; and an alarm apparatus coupled to the apparatus for sensing a change of impedance.

In accordance with another aspect of the invention, apparatus for detecting an incipient failure of an internal combustion engine timing belt, comprises: a timing belt having associated therewith a wire loop, such that in a normal operating condition, the wire loop exhibits a given loop impedance and such that the loop impedance tends to increase upon the occurrence of changes in belt condition associated with an increased risk of belt failure; an impedance measuring apparatus being inductively coupled to the wire loop for providing an output signal representative of the loop impedance; and a threshold detector responsive to the output signal for providing a signal indicative of a predetermined change in the loop impedance.

In accordance with another aspect of the invention, a method for detecting a change in a wire loop affixed to a drive belt, comprises: mutually coupling an inductance loop to the wire loop; monitoring the effective impedance of the inductance loop; detecting a change in the impedance associated with the change in the wire loop; and providing an output signal indicative of the change in the impedance.

In accordance with an aspect of the present invention, a conductive wire is embedded in a timing belt. The wire forms an endless loop in the belt, thereby forming a one-turn coil or, in other words, a shorted turn having some specified resistance and impedance. The wire may be in a simple loop or, in another embodiment, it may follow the belt contour along the inside of the belt teeth. A separate, stationary loop of wire, not embedded in the belt, is used as a sensing loop, and is arranged to be in the vicinity of the embedded one-turn coil in the belt so that magnetic or transformer type coupling is present between the two loops: the sensing loop, hereinafter referred to as the primary loop or coil and the coil loop embedded in the timing belt, hereinafter referred to as the secondary loop or coil. As is well-known from electrical engineering theory, the currents in the mutually coupled primary and secondary coils or windings of a transformer mutually influence each other. An impedance in one coil is “reflected” into the other coil due to the mutual inductive coupling. In other words, the impedance of each winding is affected by the impedance of the other winding. For example, this is the basis for a method for detecting a “shorted turn” in a transformer winding. See, for example, Handbook of Industrial Electronic Circuits by Markus and Zeluff, First Edition, McGraw-Hill Book Company, Inc., New York; 1948, on page 44.

In accordance with an aspect of the invention, a circuit arrangement is coupled to the primary winding for sensing its impedance. When a break occurs in the secondary winding such as by excessive stretching, by the breaking of a belt tooth, or by an incipient developing break in the belt, the impedance of the primary winding will be changed. Upon sensing such a change the circuit arrangement causes a warning device to operate.

The invention will be more fully understood from the following detailed description of preferred embodiments, in conjunction with the Drawing, in which

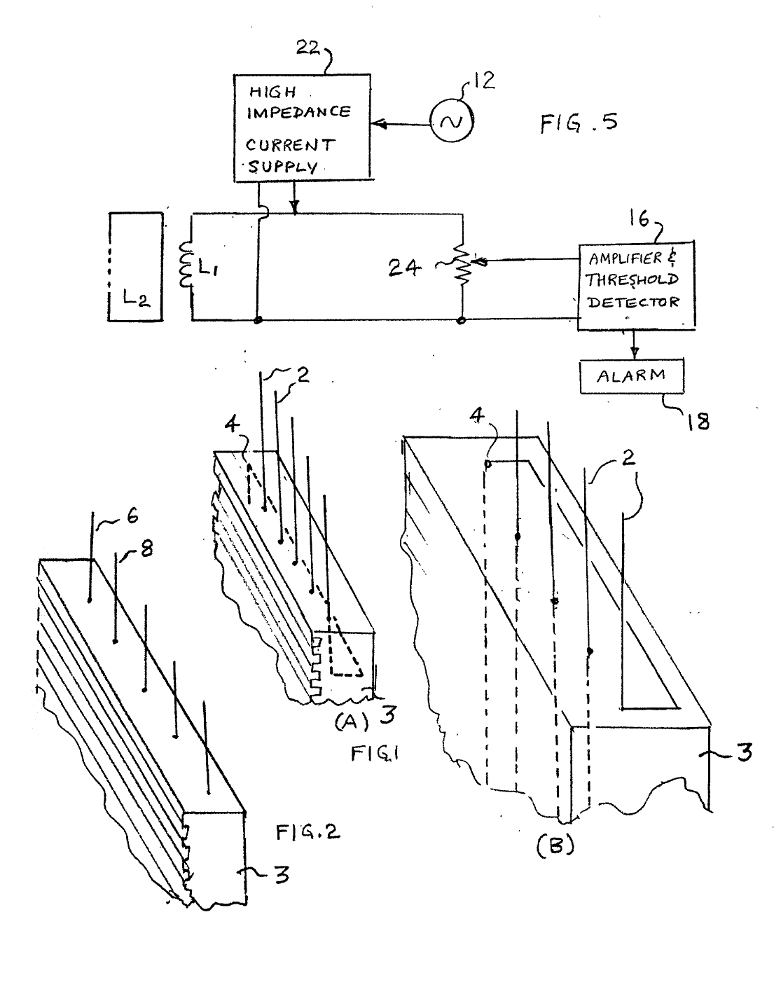

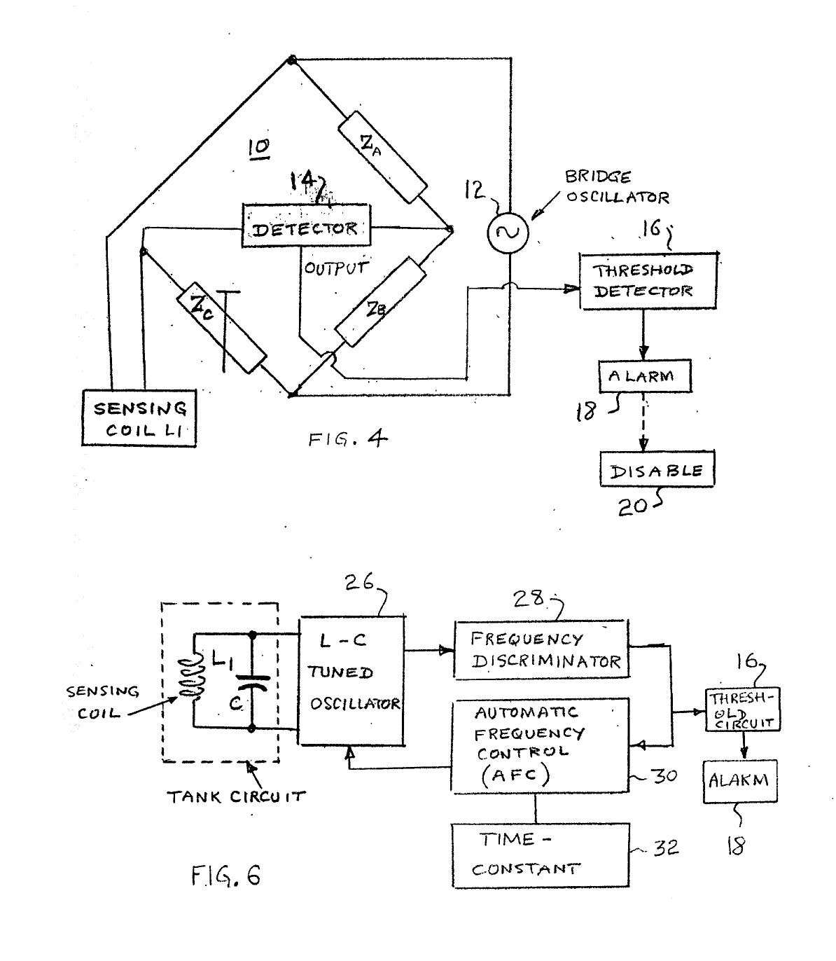

FIGS. 1 and 2 show an embedded loop, including embedded wires, as known per se in the prior art;

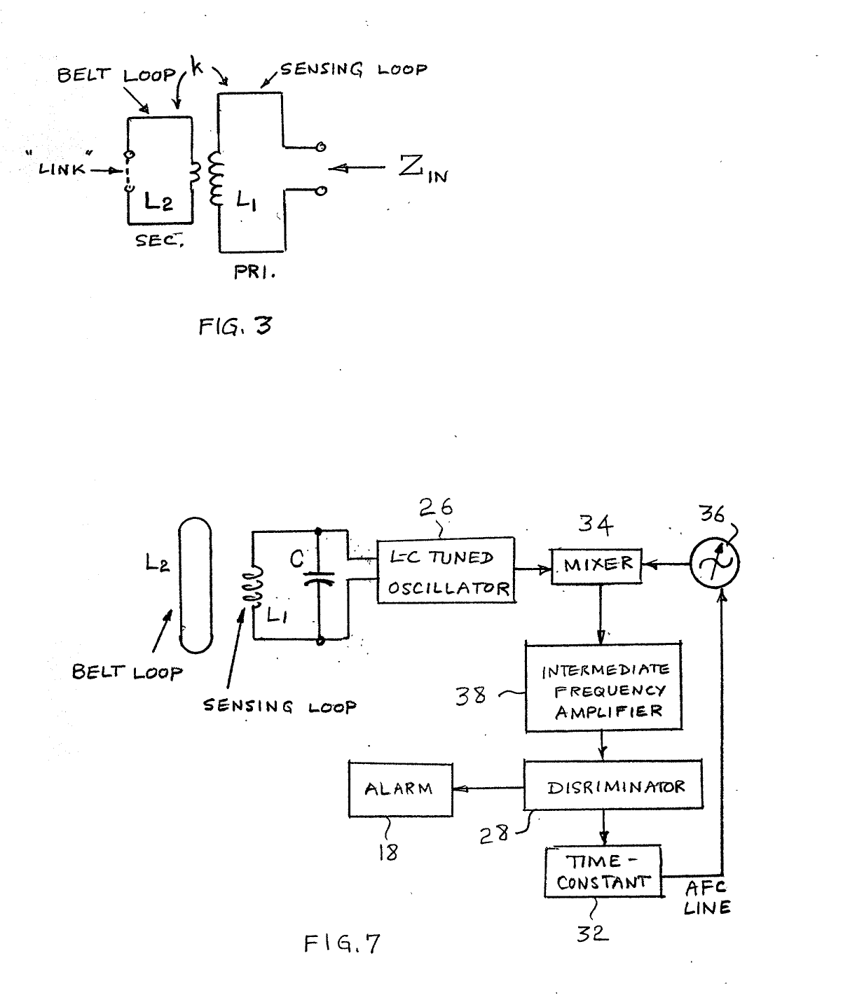

FIGS. 3 through 8 show circuits and schematics in accordance with principles of the invention;

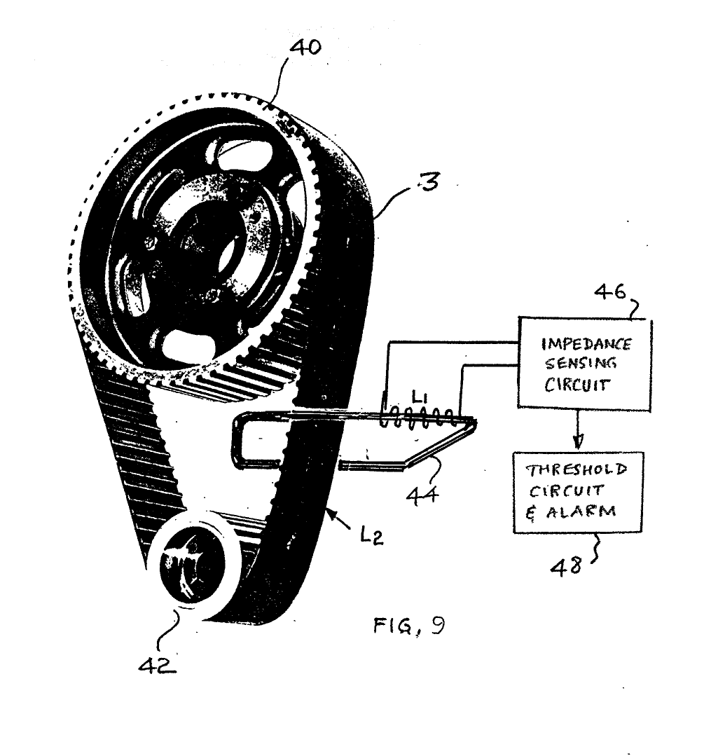

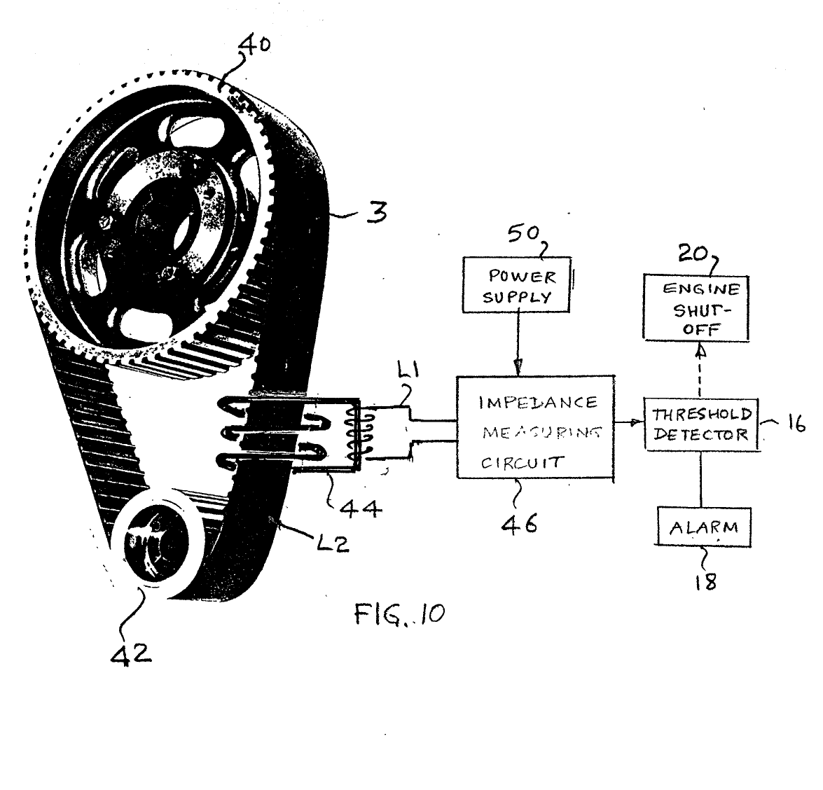

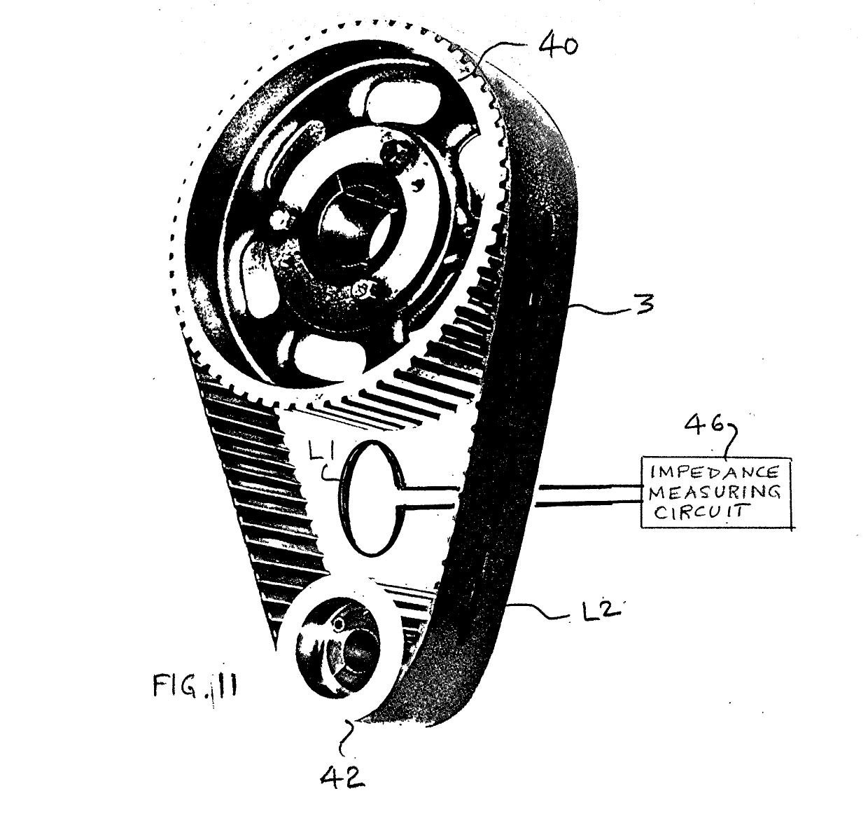

FIGS. 9 through 13 show belt and coil arrangements in accordance with principles of the invention; and

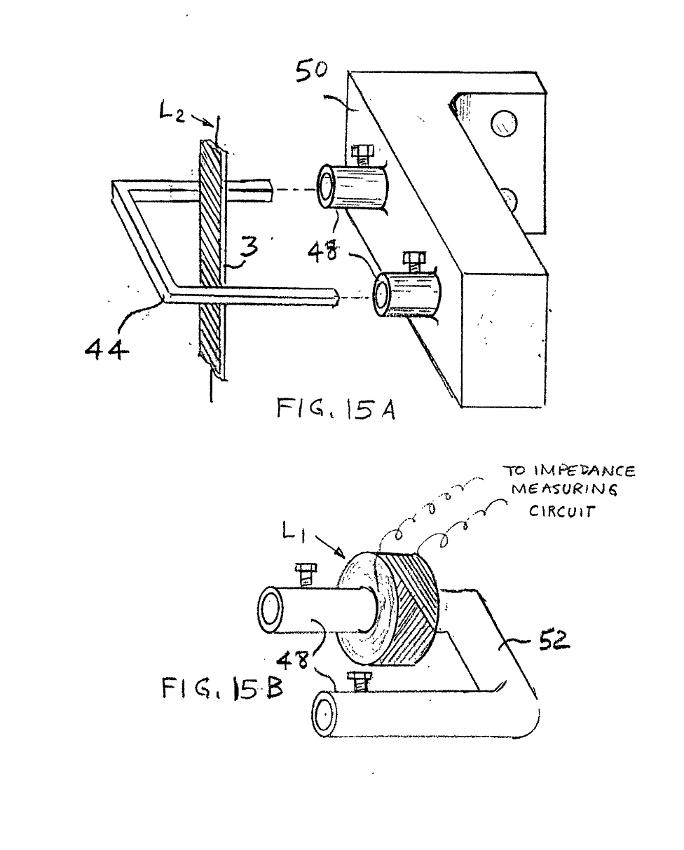

FIGS. 14 and 15 show further details of embodiments in accordance with the invention.

In the Figures, like numerals generally designate the same or similar elements. The Figures include schematic representations and are not necessarily to scale. In certain figures such as in FIGS. 9 through 13 the embedded wire(s) are not shown in the drawing but are to be understood to be present within the belts or associated closely therewith.

While the description has been in terms of a one-turn loop in the belt, in accordance with another aspect of the invention, as shown in FIG. 1A and 1B, an imbedded wire 2 in the belt 3 is arranged in a multitum coil, with the turns arranged side by side along the length of rhe belt and the ends brought together and joined at 4 at a different depth below the adjacent turns so as to form a closed secondary coil with a plurality of turns. A break anywhere in the windings of the secondary coil will cause its loop impedance to change and thereby will reflect a changed impedance into the primary coil. The change is detected by the circuit arrangement and an alarm is operated. It is noted that damage short of a complete break which increases the loop impedance sufficiently can also be detected, depending on the threshold selected. It is also noted that wires need not be embedded in the belt completely or for their whole length.

In accordance with another aspect of the invention, wires 6, 8, and so forth are arranged in the form of separate loops, side by side in the timing belt as shown in FIG. 2. Each loop is electrically isolated from its neighbors but they are coupled magnetically to each other and, as secondary coils, to the primary coil. The impedance reflected by the multiple secondary coils into the primary coil will change if any of the secondary coils is broken, such as may occur due to stress prior to the breaking of the timing belt. The change is detected by the circuit arrangement and an alarm is operated. It is however stressed that a single loop, such as any of the loops shown in FIG. 3, such as the loop formed by wire 6 in FIG. 3 is sufficient for an embodiment in accordance with the invention.

Various techniques are contemplated herein for detecting the change of impedance in the primary winding following a change in the secondary winding or secondary windings.

Various shape and location arrangements are possible for the primary or sensing coil(s), as will be explained below. It is only necessary that there be a magnetic flux linkage between primary and secondary coils for a change in the impedance of the secondary coil to be reflected into the primary coil so that it can be detected in accordance with the present invention.

FIG. 3 shows in schematic form a primary winding L1 mutually inductively coupled to a secondary winding L2, the coupling coefficient be indicated as “k”. Secondary winding L2 is normally in the form of a closed loop, being typically a single loop embedded in the timing belt. As earlier indicated, a multi-turn loop may be used or a number of side-by-side loops. When the loop is intact, it forms a closed circuit, as is indicated by the “LINK” being in place. When the loop is open-circuited by a break in the wire, this is indicated by the LINK being removed. The input impedance of the primary loop, Zᵢₙ will change when the LINK is removed, corresponding to a break in the loop. The actual amount of change in impedance depends on the actual shape, resistivity, size, and mutual arrangement of the primary and secondary coils.

In designing a system in accordance with the invention, the actual values of self-inductance and mutual inductance and the reflected impedances and impedance changes of the primary and secondary coils are readily measured experimentally by well-known techniques, including impedance bridges, Q-meters and so forth. The theory of inductors and of coupled circuits is standard in electrical engineering and may be found in various textbooks, such as Radio Engineers' Handbook by F. E. Terman, published in 1943 by McGraw-Hill Book Company, Inc., New York and London; Physical Formulae by T. S. E. Thomas, published in 1953 by Methuen and Co. Ltd., London and New York; Alternating Current Measurements by David Owen, published in 1950 by Methuen and Co. Ltd., London and New York and in other similar books.

FIG. 4 shows a bridge 10 circuit for sensing the impedance change in the primary or sensing coil following a break in the secondary coil. The secondary coil is formed by a wire loop in the timing belt of an internal combustion engine (not shown in FIG. 4). A bridge oscillator 12 supplies the bridge with alternating current operating power. Sensing coil L1 is one arm of the bridge, the other arms being Za, Zb, and Zc in conventional Wheatstone bridge type of arrangement or other convenient form of bridge configuration. Arm Zc is adjustable for balancing the bridge initially. It is contemplated that with rigid mass-produced construction, the geometries will be sufficiently invariant that a fixed balance will be sufficient for operation. The detector 14 across the bridge is sensitive to any unbalance, such as that caused in the impedance of sensing coil L1 following a break in the secondary coil L2 which corresponds to the wire loop in the timing belt. The detector output is applied to a threshold circuit 16 which is responsive to the output signal of detector 14 exceeding a predetermined limit value. Upon the threshold value being exceeded, an alarm 18 is caused to operate. The alarm may comprise a warning light, an LED (light emitting diode), a buzzer, horn, a message display, or other means of indicating. Optionally, a circuit 20 causes the engine to shut down, possibly after completion of a time delay, not shown. A time delay is useful in overcoming any problem of brief false alarms.

FIG. 5 shows a constant current, or high impedance supply applying a current through primary coil L1. Because of the high source impedance, the voltage developed across coil L1 is essentially a function of the impedance of L1. This voltage is applied through an adjustable level-setting potentiometer 24 to a threshold detector 16 for operating an alarm 18 when the voltage across coil L1 exceeds a threshold because of a break in the loop or loops of wire embedded in the belt.

FIG. 6 shows a capacitor C connected across primary or sensing coil L1 for forming a parallel resonant circuit with coil L1. This parallel resonant circuit is used as the tank or tuning circuit for an L-C (inductance/capacitance) tuned oscillator 26. The impedance of coil L1, including its effective reactance will determine the frequency of oscillation and therefore the output frequency. The output signal of oscillator 26 is applied to a frequency discriminator 28 which produces an output signal having an amplitude dependent on the frequency of oscillator 26. The output signal is applied to a threshold circuit 16 which operates an alarm 18 when the threshold is exceeded. In order to correct for slow drift in the frequency, automatic frequency control (AFC) 30 with a slow time time constant 32 forms a correction loop.

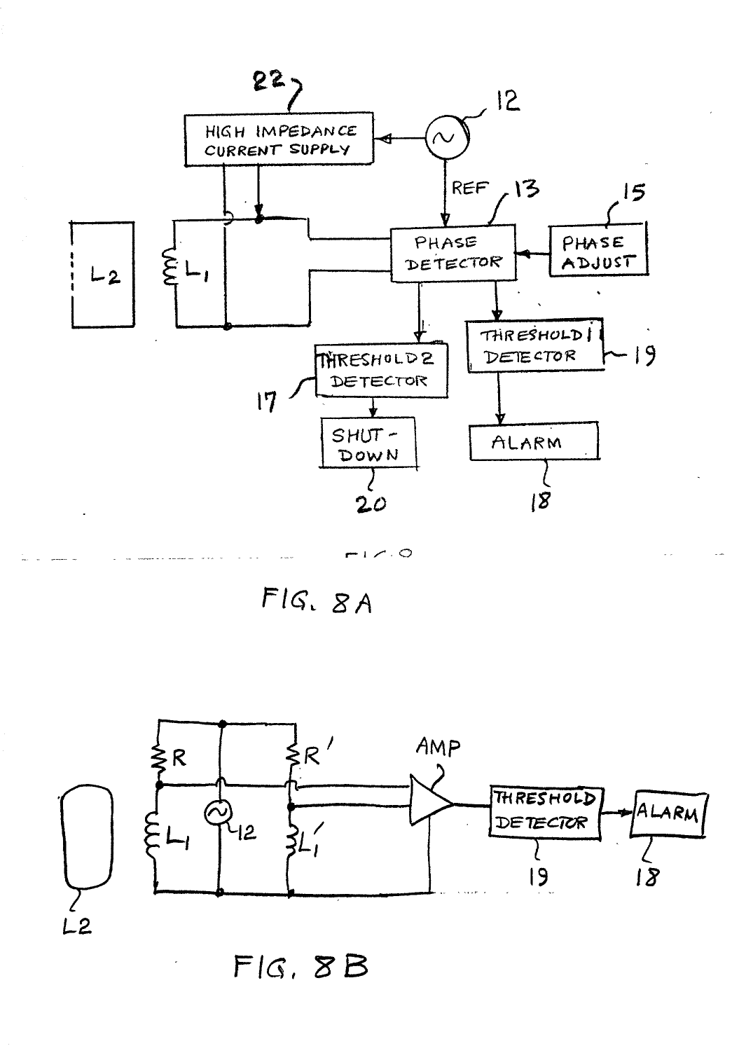

FIG. 7 shows a refinement of the system shown in FIG. 6. The oscillator output is mixed or heterodyned with a signal from a local oscillator 36. The difference in the frequencies of oscillator 26 and heterodyning oscillator 36 is made relatively small as compared with the two frequencies. The difference frequency is passed through an intermediate frequency amplifier 38. the output of amplifier 38 is applied to a discriminator 28 whose output serves to operate an alarm apparatus 18. The discriminator also provides a correction output which is coupled by way of a time constant network 32 which provides for drift correction in both oscillator 26 and oscillator 36. Correction of both is possible because it is the discriminator center frequency is fixed and the intermediate frequency change as a result of either oscillator drifting. The advantage here is that the sensitivity of the system is greatly increased, approximately by ratio of the oscillator frequency to the difference frequency. This enhancement is known, for example, in measurement techniques for detecting very small changes in capacitance. See, for example, the aforementioned Handbook by Markus and Zeluff on page 25. In the embodiment of the present invention, it is a small change in inductance that is detected.

FIG. 8A shows shows in schematic form secondary coil L2 which represents the wire arrangement embedded in the belt and L1, the primary coil which is coupled inductively to coil L2. A high impedance current supply 22 driven by oscillator 12 applies current to coil L1 so that a voltage whose amplitude and phase depends on the impedance of coil L1 appears across coil L1. This voltage is applied to the input of a phase detector 13 which receives a reference signal from oscillator 12 on its other input. A phase adjust circuit 15 is provided for trimming the operation of phase detector 13. The output of phase detector 13 is applied to a threshold detector 17 which operates to cause engine shutdown by way of unit 20 when the threshold is exceeded. The output of phase detector 13 is applied to a threshold detector 19 which operates alarm 18 when the threshold is exceeded. In the arrangement of FIG. 8, it is the change of phase angle of the impedance of coil L1 which is detected when the impedance of coil L2 is changed by breaking of the embedded wire.

In FIG. 8B, a source 12 of an alternating voltage supplies current through a resistor R to primary coil L1 which is inductively coupled to coil L2 which represents the wire embedded in the belt (not shown). Source 12 supplies current through a resistor R′ to a coil L1′. The junction of L1 and R is coupled to a signal input terminal of a differential amplifier AMP whose output is applied to a threshold detector 19 having an output coupled to an alarm 18. The junction of L1′ and R′ is coupled to the other signal input terminal of differential amplifier AMP.

In operation, if R=R′ and if the impedance of L1′ is the same as the impedance of L1 as modified by its mutual inductance coupling to coil L2, then both input terminals of amplifier AMP will be at the same potential and its output will be zero. If coil L2 becomes open-circuit by the embedded wire breaking, the mutual inductance coupling to L1 will cause the effective impedance of L1 to change and an unbalance voltage will appear across the input terminals of amplifier AMP, causing it apply an output voltage to threshold detector 19, thereby causing alarm 18 to operate.

FIG. 9 shows in diagrammatic form and not necessarily to scale, a camshaft pulley 40 being driven by a crankshaft pulley 42. A magnetic core 44 in the form of a loop of a magnetic core material encloses one side of belt 3, thereby enclosing the wire of secondary coil L2. Loop 44 has a primary coil L1 wound thereon. Coils L1 and L2 are therefore mutually coupled by way of core 44. An impedance change in coil L2 will therefore cause a change in impedance in coil L1 for sensing by an impedance sensing circuit 46 and threshold circuit 48, and operating an alarm in the manner described upon breakage of the wire of coil L2. The problem of threading belt 3 through a loop is readily accommodated by having a recloseable gap in core 44, such as by a demountable portion thereof which is held together by a sleeve or clamp, not shown.

In FIG. 10, core 44 encloses coil L2 by several turns, thereby modifying the sensitivity of the system.

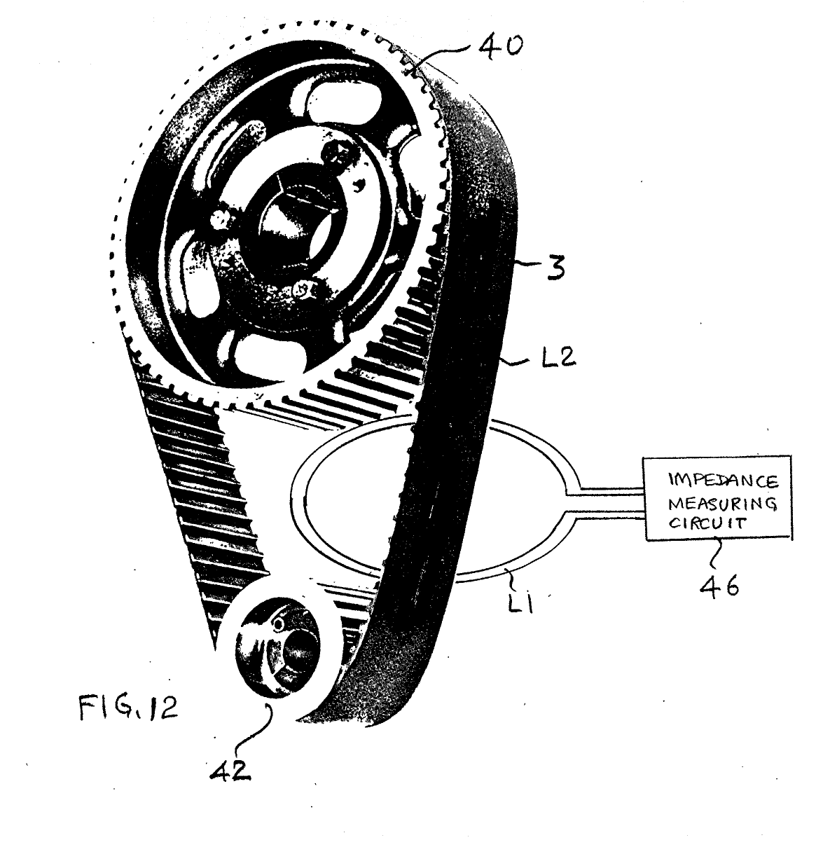

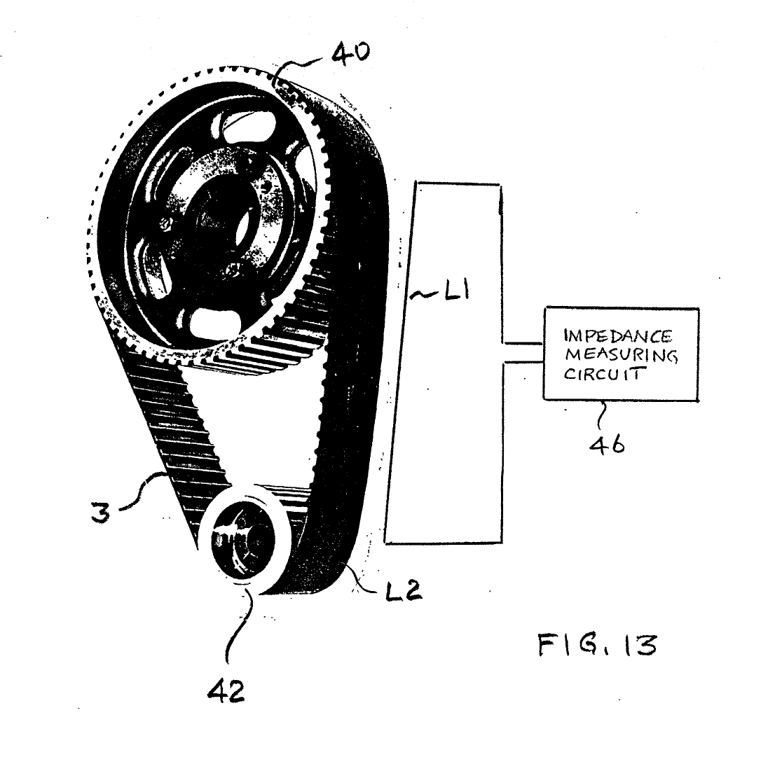

FIGS. 11 and 12 show various possible configurations for coil L1. The exact shape of coil L1 is not critical. In order to achieve a large coupling to the embedded wire loop, it is preferable for coil L1 to enclose as much area as possible of the area enclosed by the embedded loop between the pulleys 40 and 42. The presence of other metal parts in the vicinity of L1 introduces other impedances in the effective impedance of L1, but since the geometry of the configuration is fixed, these impedances are taken into account in an initial adjustment and it is the subsequent change in effective inductance of L1 which indicates a break in the embedded loop wire.

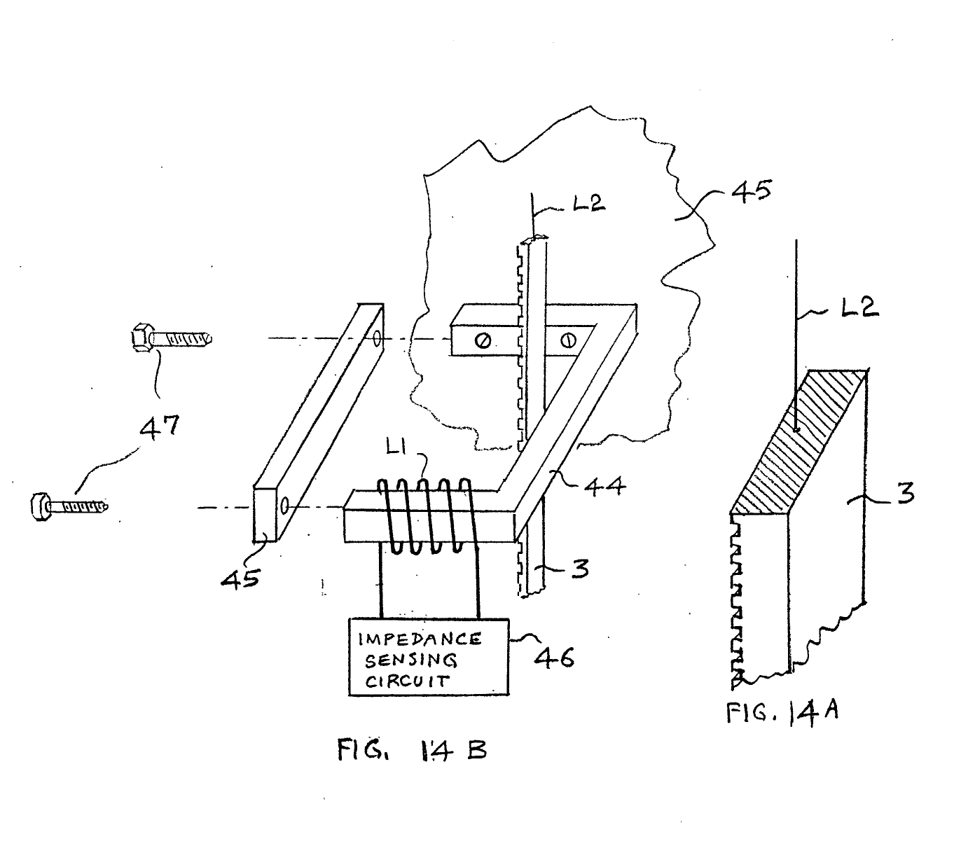

FIG. 13 show L1 in the form of a generally straight or curved conductor along side the wire of coil L2. As was explained, it is merely necessary for L1 and L2 to exhibit a degree of mutual inductance for the impedance of L1 to be affected by a break in L2. Mutual inductance also exists between generally parallel conductors as is known from the principles of electrical engineering.

FIG. 14B shows a magnetic core material in a U-shape portion 44 with a detachable portion 45 for forming a closed magnetic loop when attached to portion 44 by screws 47. Portion 44 can be attached to part of the engine frame or block 45. Coil L2, in the form of an embedded wire in timing belt 3, as shown enlarged in FIG. 14A, passes through the closed magnetic loop formed by together with belt 3. Coil L2 is wound on a portion of the closed magnetic loop and is connected to impedance measuring circuit 46. The threshold and alarm features for operating in conjunction with circuit 46 are not shown.

FIG. 15A shows a detachable U-shaped magnetic core material 44 for attachment by set screws to terminal receptacles 48 in a plastic body portion 50 adapted and having mounting holes for being attached to part of an engine block directly or by way of a mounting bracket (not shown).

FIG. 15B shows a view of terminal receptacles 48 without body portion 50, showing that receptacles 48 continue inside body portion 50 to form a closed magnetic loop 52. Loop 52 passes through coil L2, here shown in the form of a multilayer coil, and thus links the flux threading coils L1 and L2 for mutual inductive coupling.

There has been herein described a system, method, and apparatus for detecting breakage and incipient breakage of a belt in a belt driven apparatus. The belt may be flat, vee, or a toothed or cogged belt, commonly referred to as a timing belt.

More particularly, in the described embodiments, the breaking of a wire loop embedded in a timing belt for driving the camshaft in an internal combustion engine or in any other timing belt drive using a toothed or cogged belt is detected.

A sensing coil is mutually inductively coupled with the coil formed by a wire loop embedded in a timing belt as for a camshaft drive in an internal combustion engine. When the embedded wire loop breaks, which can occur before total belt failure, a circuit senses the change in impedance in the sensing coil and operates an alarm. The method is non-contacting with the belt and requires no sliding contacts.

Reference is made to theoretical material on pages 98 and 99 from the aforementioned book Physical Formulae by T. S. E. Thomas, published in 1953 by Methuen and Co. Ltd., London and New York relating to transformers, indicating the effect of the secondary circuit on the primary circuit impedance.

Helpful theoretical material is to be found on pages 48-73 and 148-149 of the afore-mentioned book Radio Engineers′ Handbook by F. E. Terman, published in 1943 by McGraw-Hill Book Company, Inc., New York and London on self-inductance and mutual inductance in coupled circuits.

While the invention has been described by way of exemplary embodiments, it will be understood by one of skill in the art to which it pertains that various changes, modifications can be made without departing from the spirit of the invention. For example, analog circuits and techniques have been described for carrying out the functions of impedance change detection and so forth. However, it will be understood that signal processing can be readily implemented using digital techniques which for the most part are entirely equivalent. Thus, analog to digital conversion can be carried out and the threshold detection performed by digital comparison. Furthermore, there are various other techniques known for impedance sensing and such techniques are well known in the art of alternating current bridges and also in the art of digital inductance measuring instrumentation.

What is claimed is:

1. Apparatus for detecting a fault in a wire loop in a drive belt, comprising
an inductance loop coupled by mutual inductance to said wire loop;
impedance-measuring apparatus coupled to said inductance loop; and
threshold detecting apparatus coupled to said impedance-measuring apparatus.

2. Apparatus for detecting a fault in a wire loop in accordance with claim 1, wherein said inductance loop comprises a plurality of turns.

3. Apparatus for detecting a fault in a wire loop in accordance with claim 1, wherein said impedance-measuring apparatus comprises a bridge circuit coupled to said inductance loop.

4. Apparatus for detecting a fault in a wire loop in accordance with claim 3, wherein said impedance-measuring apparatus comprises a threshold circuit coupled to said bridge circuit.

5. Apparatus for detecting a fault in a wire loop in accordance with claim 1, wherein said impedance-measuring apparatus comprises a tuned circuit oscillator wherein said inductance loop forms part of said tuned circuit.

6. Apparatus for detecting a fault in a wire loop in accordance with claim 5, wherein said impedance-measuring apparatus comprises a heterodyne circuit for detecting a change of operating frequency of said oscillator.

7. Apparatus for detecting a fault in a wire loop in accordance with claim 5, wherein said wire loop and said inductance loop are mutually coupled by way of a magnetic core.

8. Apparatus for detecting a change in a wire loop associated with a drive belt, comprising:
means inductively coupled to said wire loop for sensing a change of impedance of said wire loop; and
alarm means coupled to said means for sensing a change of impedance.

9. Apparatus for detecting a change in a wire loop in accordance with claim 8, wherein said means for sensing a change of impedance of said wire loop comprises:
means for measuring impedance; and
means for providing mutual inductive coupling between said means for measuring impedance and said wire loop.

10. Apparatus for detecting a change in a wire loop in accordance with claim 9, wherein said means for detecting a change in impedance comprises:
means coupled to said to an output of said means for measuring impedance for detecting a predetermined change in impedance measured by said means for measuring impedance.

11. Apparatus for detecting an incipient failure of an internal combustion engine timing belt, comprising:
a timing belt having associated therewith a wire loop, such that in a normal operating condition, said wire loop exhibits a given loop impedance and such that said loop impedance tends to increase upon the occurrence of changes in belt condition associated with an increased risk of belt failure;
an impedance measuring apparatus being inductively coupled to said wire loop for providing an output signal representative of said loop impedance; and
a threshold detector responsive to said output signal for providing a signal indicative of a predetermined change in said loop impedance.

12. Apparatus for detecting an incipient failure of an internal combustion engine timing belt in accordance with claim 11, wherein said threshold detector comprises an alarm indicator responsive to said signal indicative of a predetermined change in said loop impedance.

13. Apparatus for detecting an incipient failure of an internal combustion engine timing belt in accordance with claim 11, wherein:
said wire loop is embedded in said timing belt.

14. Apparatus for detecting an incipient failure of an internal combustion engine timing belt in accordance with claim 11, wherein:
said wire loop is embedded in said timing belt following a path associated with individual teeth of said timing belt such that the breakage of a belt tooth tends to cause said wire loop to break.

15. Apparatus for detecting an incipient failure of an internal combustion engine timing belt in accordance with claim 11, wherein:
said wire loop comprises a plurality of turns.

16. Apparatus for detecting an incipient failure of an internal combustion engine timing belt in accordance with claim 11, wherein:
means for measuring impedance comprises a bridge circuit; and
said means for providing mutual inductive coupling between said means for measuring impedance and said wire loop comprises an inductive loop.

17. Apparatus for detecting an incipient failure of an internal combustion engine timing belt in accordance with claim 11, wherein:
said means for providing mutual inductive coupling between said means for measuring impedance and said wire loop comprises an inductive loop.

18. Apparatus for detecting an incipient failure of an internal combustion engine timing belt in accordance with claim 17, wherein:
means for measuring impedance comprises a bridge circuit.

19. Apparatus for detecting an incipient failure of an internal combustion engine timing belt in accordance with claim 17, wherein:
said means for measuring impedance comprises an oscillator; and
said inductive loop forms part of a tuned circuit of said oscillator.

20. Apparatus for detecting an incipient failure of an internal combustion engine timing belt in accordance with claim 19, wherein:
said means for measuring impedance comprises a heterodyne frequency discriminator.

21. A method for detecting a change in a wire loop affixed to a drive belt, comprising:
mutually coupling an inductance loop to said wire loop;
monitoring the effective impedance of said inductance loop;
detecting a change in said impedance associated with said change in said wire loop; and
providing an output signal indicative of said change in said impedance.

22. A method in accordance with claim 21, comprising:
providing a signal for stopping an engine upon the occurrence of said output signal indicative of said change in said impedance.

23. A method in accordance with claim 21, comprising:
providing an alarm signal upon the occurrence of said output signal indicative of said change in said impedance.

24. Apparatus for detecting a break in a wire loop in a drive belt, comprising
an inductance loop coupled by mutual inductance to said wire loop;
impedance-measuring apparatus coupled to said inductance loop; and
threshold detecting apparatus coupled to said impedance-measuring apparatus.

25. Apparatus for detecting a break in a wire loop in accordance with claim 24, wherein said inductance loop comprises a plurality of turns.

26. Apparatus for detecting a break in a wire loop in accordance with claim 24, wherein said impedance-measuring apparatus comprises a bridge circuit coupled to said inductance loop.

27. Apparatus for detecting a break in a wire loop in accordance with claim 26, wherein said impedance-measuring apparatus comprises a threshold circuit coupled to said bridge circuit.

28. Apparatus for detecting a break in a wire loop in accordance with claim 24, wherein said impedance-measuring apparatus comprises a tuned circuit oscillator wherein said inductance loop forms part of said tuned circuit.

29. Apparatus for detecting a break in a wire loop in accordance with claim 28, wherein said impedance-measuring apparatus comprises a heterodyne circuit for detecting a change of operating frequency of said oscillator.

30. Apparatus for detecting a break in a wire loop in accordance with claim 28, wherein said wire loop and said inductance loop are mutually coupled by way of a magnetic core.
